(19) United States
(12) Patent Application Publication
(10) Pub. No.: US 2026/0074704 A1
(43) Pub. Date: Mar. 12, 2026

(54) Simultaneously Sampled Data Acquisition Device

(71) Applicant: NATIONAL INSTRUMENTS CORPORATION, Austin, TX (US)

(72) Inventors: Adam H. Dewhirst, Austin, TX (US); Chong Meng Lee, Penang (MY)

(21) Appl. No.: 18/828,512

(22) Filed: Sep. 9, 2024

(51) Int. Cl. H03M 1/00; H03M 1/10

(52) U.S. Cl. CPC H03M 1/001; H03M 1/1009

(57) ABSTRACT

Apparatuses, systems, and methods for data acquisition (DAQ) devices, and more particularly to apparatuses, systems, and methods for a simultaneously sampled DAQ device with flexible input terminal configurations. A DAQ device can be configured, e.g., via programmable driver software, to simultaneously sample analog input (AI) channels in differential mode or simultaneously sample AI+ and AI− signals in a single ended mode (RSE or NRSE). In addition, a DAQ device can be configured, e.g., via programmable driver software, to simultaneously sample AI channels in differential mode or pseudo-simultaneously sample AI+ and AI− signals in single ended mode (RSE or NRSE), e.g., all AI+ channels sampled simultaneously and then all AI− channels sample simultaneously.

### TECHNICAL FIELD

The invention relates to data acquisition (DAQ) devices, and more particularly to apparatuses, systems, and methods for a simultaneously sampled DAQ device with flexible input terminal configurations.

### DESCRIPTION OF THE RELATED ART

Currently, there are generally two categories of data acquisition (DAQ) devices—multiplexed multifunction input/output (MIO) devices and simultaneously sampled multifunction input/output (SMIO) devices. MIO devices refer to a category of DAQ devices that can multiplex many input channels down to a single analog to digital converter (ADC). SMIO devices refer to a category of DAQ devices that have a per channel ADC that allows for higher speeds and simultaneous sampling of each channel. Thus, for cost reasons, SMIO devices tend to have a higher cost per channel than MIO devices while offering simultaneous sampling across a limited number of channels. MIO DAQ devices tend to offer three different input configurations: differential mode (DIFF), referenced single-ended mode (RSE), and non-referenced single-ended mode (NRSE). In a DIFF configuration, an ADC can measure a difference between two analog input (AI) signals (e.g., a positive AI signal (AI+) and a negative AI signal (AI−). In an RSE configuration, an ADC can measure a difference between an AI signal and a common ground reference. In an NRSE configuration, an ADC can measure a difference between an AI signal and a common remote ground reference (e.g., often referred to as AI sense). Note that, of these configurations, DIFF generally offers higher performance than RSE or NRSE, however, RSE and NRSE can offer simpler configurations (e.g., such as simpler wiring) and higher channel density since all channels can share a common reference thus reducing a number of signal pins and wires required as compared to DIFF and allowing for higher channel density for a given connector or package size. Further, SMIO DAQ devices tend to only support DIFF configurations. Thus, systems originally designed with MIO DAQ devices (e.g., using an RSE or NRSE configuration) cannot be readily upgraded to SMIO DAQ devices. Further, SMIO DAQ devices only support half the I/O density of MIO DAQ devices since there is no support for RSE or NRSE. Therefore, improvements are desirable.

### SUMMARY

Embodiments described herein relate to DAQ devices, and more particularly to apparatuses, systems, and methods for a simultaneously sampled DAQ device with flexible input terminal configurations. For example, a DAQ device can be configured, e.g., via programmable driver software, to simultaneously sample analog input (AI) channels in differential mode or simultaneously sample AI+ and AI− signals in a single ended mode (RSE or NRSE). As another example, a DAQ device can be configured, e.g., via programmable driver software, to simultaneously sample AI channels in differential mode or pseudo-simultaneously sample AI+ and AI− signals in single ended mode (RSE or NRSE), e.g., all AI+ channels sampled simultaneously and then all AI− channels sample simultaneously.

As an example, in some embodiments, a circuit can include first selection circuitry that is in communication with a first instrumentation amplifier and second selection circuitry that is in communication with a second instrumentation amplifier. The first selection circuitry can be configured (e.g., via a programmable driver software) to output one of a positive analog input signal or a positive calibration signal. The second selection circuitry can be configured (e.g., via the programmable driver software) to output one of a negative analog input signal, the positive calibration signal, or a ground reference signal. The first instrumentation amplifier can be configured (e.g., via the programmable driver software) to output a first analog signal corresponding to a voltage difference between a first signal output from the first selection circuitry and a second signal output from the second selection circuitry. The second instrumentation amplifier can be configured (e.g., via the programmable driver software) to output a second analog signal corresponding to a voltage difference between the second signal output from the second selection circuitry and the ground reference signal. The circuit can further include a first analog to digital converter that can be configured (e.g., via the programmable driver software) to digitize the first analog signal and a second analog to digital converter that can be configured (e.g., via the programmable driver software) to digitize the second analog signal.

As another example, in some embodiments, a circuit can include first selection circuitry and second selection circuitry that are that is in communication with an instrumentation amplifier. The first selection circuitry can be configured (e.g., via a programmable driver software) to output one of a positive analog input signal, a negative analog input signal, or a positive calibration signal. The second selection circuitry can be configured (e.g., via the programmable driver software) to output one of the negative analog input signal or a ground reference signal. The instrumentation amplifier can be configured (e.g., via the programmable driver software) to output a first analog signal corresponding to a voltage difference between a first signal output from the first selection circuitry and a second signal output from the second selection circuitry. In addition, the circuit can include an analog to digital converter that can be configured (e.g., via the programmable driver software) to digitize the first analog signal.

As a further example, in some embodiments, a DAQ device can include a plurality of signal selection circuits and a plurality of amplification circuits. Note that each signal selection circuit can have a corresponding amplification circuit. Each signal selection circuit can be configured to output, to a corresponding amplification circuit, a first analog signal and a second analog signal. The first analog signal can include and/or be one of a positive analog input signal or a positive calibration signal and the second analog signal can include and/or be one of a negative analog input signal, the positive calibration signal, or a ground reference signal. Further, each amplification circuit can be configured to at least output a third analog signal corresponding to a voltage difference between the first analog signal and the second analog signal. In some configurations, each amplification circuit can also be configured to output a fourth analog signal corresponding to a voltage difference between the second signal and the ground reference signal.

As a yet further example, in some embodiments, a DAQ device can include a plurality of signal selection circuits and a plurality of amplification circuits. Note that each signal selection circuit can have a corresponding amplification circuit. Each signal selection circuit can be configured to output, to the corresponding amplification circuit, a first analog signal and a second analog signal. The first analog signal can include and/or be a positive analog input signal, a negative analog input signal, or a positive calibration signal and the second analog signal can include and/or be one of the negative analog input signal or a ground reference signal. Further, each amplification circuit can be configured to output a third analog signal corresponding to a voltage difference between the first analog signal and the second analog signal.

Note that the techniques described herein may be implemented in and/or used with a number of different types of systems, including but not limited to Peripheral Component Interconnect (PCI) DAQ devices, compact PCI DAQ devices, universal serial bus (USB) DAQ devices, various DAQ chassis, and any of various other computing devices.

This Summary is intended to provide a brief overview of some of the subject matter described in this document. Accordingly, it will be appreciated that the above-described features are only examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE DRAWINGS

A better understanding of the disclosed embodiments can be obtained when the following detailed description of the preferred embodiments is considered in conjunction with the following drawings.

FIG. 1 illustrates an example of a computer system, according to some embodiments.

FIG. 2 illustrates an example block diagram of a server 104, according to some embodiments.

FIG. 3 illustrates an example of a block diagram of a simultaneously sampled DAQ device.

FIGS. 4 and 5 illustrate examples of block diagrams of circuits for SMIO DAQ devices, according to some embodiments.

FIGS. 6 and 7 illustrate examples of simplified block diagrams of circuits for SMIO DAQ devices, according to some embodiments.

FIG. 8 illustrates an example of a simplified block diagram of a DAQ device, according to some embodiments.

FIG. 9 illustrates a block diagram of an example of a method for configuring a DAQ device, according to some embodiments.

While the features described herein may be susceptible to various modifications and alternative forms, specific embodiments thereof are shown by way of example in the drawings and are herein described in detail. It should be understood, however, that the drawings and detailed description thereto are not intended to be limiting to the particular form disclosed, but on the contrary, the intention is to cover all modifications, equivalents and alternatives falling within the spirit and scope of the subject matter as defined by the appended claims.

### DETAILED DESCRIPTION

### Acronyms

Various acronyms are used throughout the present disclosure. Definitions of the most prominently used acronyms that may appear throughout the present disclosure are provided below:
DAQ: Data Acquisition
DUT: Device Under Test
UUT: Unit Under Test
SMIO: Simultaneously Sampled Multifunction Input/Output
GUI: Graphical User Interface

### Terms The following is a glossary of terms used in this disclosure:

Device Under Test (DUT) or Unit Under Test (UUT)—A physical device or component that is being tested.

Memory Medium—Any of various types of non-transitory memory devices or storage devices. The term “memory medium” is intended to include an installation medium, e.g., a CD-ROM, floppy disks, or tape device; a computer system memory or random-access memory such as DRAM, DDR RAM, SRAM, EDO RAM, Rambus RAM, etc.; a non-volatile memory such as a Flash, magnetic media, e.g., a hard drive, or optical storage; registers, or other similar types of memory elements, etc. The memory medium may include other types of non-transitory memory as well or combinations thereof. In addition, the memory medium may be located in a first computer system in which the programs are executed, or may be located in a second different computer system which connects to the first computer system over a network, such as the Internet. In the latter instance, the second computer system may provide program instructions to the first computer for execution. The term “memory medium” may include two or more memory mediums which may reside in different locations, e.g., in different computer systems that are connected over a network. The memory medium may store program instructions (e.g., embodied as computer programs) that may be executed by one or more processors.

Carrier Medium—a memory medium as described above, as well as a physical transmission medium, such as a bus, network, and/or other physical transmission medium that conveys signals such as electrical, electromagnetic, or digital signals.

Programmable Hardware Element—includes various hardware devices comprising multiple programmable function blocks connected via a programmable interconnect. Examples include FPGAs (Field Programmable Gate Arrays), PLDs (Programmable Logic Devices), FPOAs (Field Programmable Object Arrays), and CPLDs (Complex PLDs). The programmable function blocks may range from fine grained (combinatorial logic or look up tables) to coarse grained (arithmetic logic units or processor cores). A programmable hardware element may also be referred to as “reconfigurable logic”.

Computer System (or Computer)—any of various types of computing or processing systems, including a personal computer system (PC), mainframe computer system, workstation, network appliance, Internet appliance, personal digital assistant (PDA), television system, grid computing system, or other device or combinations of devices. In general, the term “computer system” can be broadly defined to encompass any device (or combination of devices) having at least one processor that executes instructions from a memory medium.

Processing Element (or Processor)—refers to various elements or combinations of elements that are capable of performing a function in a device, such as a user equipment or a cellular network device. Processing elements may include, for example: processors and associated memory, portions or circuits of individual processor cores, entire processor cores, processor arrays, circuits such as an ASIC (Application Specific Integrated Circuit), programmable hardware elements such as a field programmable gate array (FPGA), as well any of various combinations of the above.

Program—the term “program” is intended to have the full breadth of its ordinary meaning. The term “program” includes 1) a software program which may be stored in a memory and is executable by a processor or 2) a hardware configuration program useable for configuring a programmable hardware element.

Software Program—the term “software program” is intended to have the full breadth of its ordinary meaning, and includes any type of program instructions, code, script and/or data, or combinations thereof, that may be stored in a memory medium and executed by a processor. Exemplary software programs include programs written in text-based programming languages, such as C, C++, Pascal, Fortran, Cobol, Java, assembly language, etc.; graphical programs (programs written in graphical programming languages); assembly language programs; programs that have been compiled to machine language; scripts; and other types of executable software. A software program may comprise two or more software programs that interoperate in some manner.

Automatically—refers to an action or operation performed by a computer system (e.g., software executed by the computer system) or device (e.g., circuitry, programmable hardware elements, ASICs, etc.), without user input directly specifying or performing the action or operation. Thus, the term “automatically” is in contrast to an operation being manually performed or specified by the user, where the user provides input to directly perform the operation. An automatic procedure may be initiated by input provided by the user, but the subsequent actions that are performed “automatically” are not specified by the user, i.e., are not performed “manually”, where the user specifies each action to perform. For example, a user filling out an electronic form by selecting each field and providing input specifying information (e.g., by typing information, selecting check boxes, radio selections, etc.) is filling out the form manually, even though the computer system must update the form in response to the user actions. The form may be automatically filled out by the computer system where the computer system (e.g., software executing on the computer system) analyzes the fields of the form and fills in the form without any user input specifying the answers to the fields. As indicated above, the user may invoke the automatic filling of the form, but is not involved in the actual filling of the form (e.g., the user is not manually specifying answers to fields but rather they are being automatically completed). The present specification provides various examples of operations being automatically performed in response to actions the user has taken.

Approximately—refers to a value that is almost correct or exact. For example, approximately may refer to a value that is within 1 to 10 percent of the exact (or desired) value. It should be noted, however, that the actual threshold value (or tolerance) may be application dependent. For example, in some embodiments, “approximately” may mean within 0.1% of some specified or desired value, while in various other embodiments, the threshold may be, for example, 2%, 3%, 5%, and so forth, as desired or as required by the particular application.

Concurrent—refers to parallel execution or performance, where tasks, processes, or programs are performed in an at least partially overlapping manner. For example, concurrency may be implemented using “strong” or strict parallelism, where tasks are performed (at least partially) in parallel on respective computational elements, or using “weak parallelism”, where the tasks are performed in an interleaved manner, e.g., by time multiplexing of execution threads.

Various components may be described as “configured to” perform a task or tasks. In such contexts, “configured to” is a broad recitation generally meaning “having structure that” performs the task or tasks during operation. As such, the component can be configured to perform the task even when the component is not currently performing that task (e.g., a set of electrical conductors may be configured to electrically connect a module to another module, even when the two modules are not connected). In some contexts, “configured to” may be a broad recitation of structure generally meaning “having circuitry that” performs the task or tasks during operation. As such, the component can be configured to perform the task even when the component is not currently on. In general, the circuitry that forms the structure corresponding to “configured to” may include hardware circuits.

Various components may be described as performing a task or tasks, for convenience in the description. Such descriptions should be interpreted as including the phrase “configured to.” Reciting a component that is configured to perform one or more tasks is expressly intended not to invoke 35 U.S.C. § 112(f) interpretation for that component.

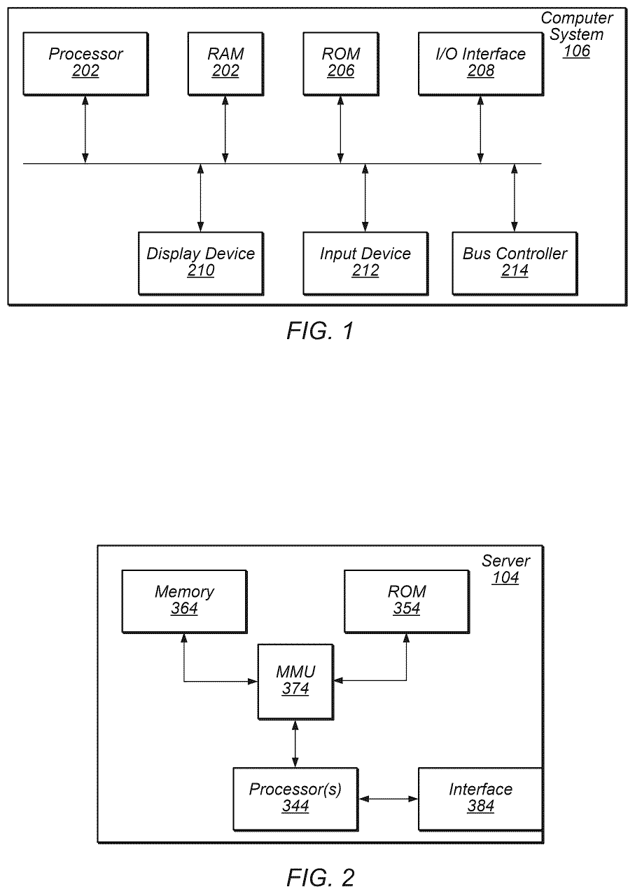

### FIG. 1: Computer System

FIG. 1 illustrates a computer system 106 that may include a processor 202, random access memory (RAM) 204, nonvolatile memory 206, a display device 210, an input device 212, an I/O interface 208 (e.g., such as a universal serial bus (USB) for coupling to sensors, and a bus controller 214, e.g., for interfacing/connecting to an expansion bus, such as a PCI (Peripheral Component Interconnect) expansion bus, among other examples of buses. For example, the computer system 106 may include hardware and software components for implementing or supporting implementation of features described herein. The processor 202 may be configured to implement or support implementation of part or all of the methods described herein, e.g., by executing program instructions stored on a memory medium (e.g., a non-transitory computer-readable memory medium). Alternatively, the processor 202 may be configured as a programmable hardware element, such as an FPGA (Field Programmable Gate Array), or as an ASIC (Application Specific Integrated Circuit), or a combination thereof. Alternatively (or in addition) the processor 202, in conjunction with one or more of the other components 204, 206, 208, 210, 212, and/or 214 may be configured to implement or support implementation of part or all of the features described herein.

In addition, as described herein, processor(s) 202 may be comprised of one or more processing elements. In other words, one or more processing elements may be included in processor(s) 202. Thus, processor(s) 202 may include one or more integrated circuits (ICs) that are configured to perform the functions of processor(s) 202. In addition, each integrated circuit may include circuitry (e.g., first circuitry, second circuitry, etc.) configured to perform the functions of processor(s) 202.

As shown, the computer system 106 may include a processor that is coupled to a random access memory (RAM) and a nonvolatile memory. The computer system 106 may also include user interface elements for receiving user input and a display device for presenting output. For example, the user interface elements may include any of various elements, such as a display (which may be a touchscreen display), a keyboard (which may be a discrete keyboard or may be implemented as part of a touchscreen display), a mouse, a microphone and/or speakers, one or more cameras, one or more buttons, and/or any of various other elements capable of providing information to a user and/or receiving or interpreting user input. The computer system 106 may also include an Input/Output (I/O) interface that may be communicatively coupled (e.g., locally via a system bus, or remotely via a network and/or serial interface) to various hardware elements (e.g., such as FPGAs, data acquisition boards, controllers, and the like).

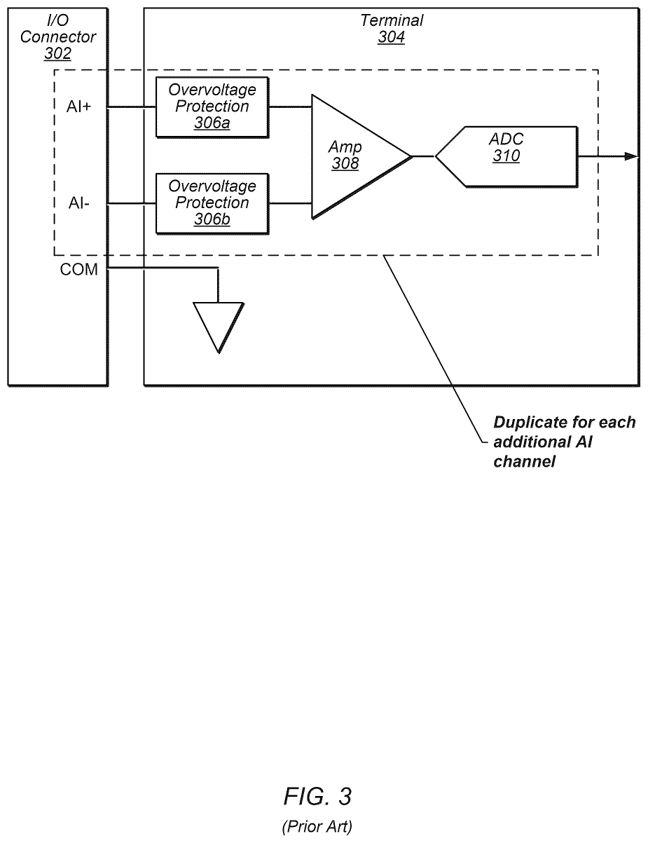

### FIG. 2: Server

FIG. 2 illustrates an example block diagram of a server 104, according to some embodiments. It is noted that the server of FIG. 2 is merely one example of a possible server. As shown, the server 104 may include processor(s) 344 which may execute program instructions for the server 104. The processor(s) 344 may also be coupled to memory management unit (MMU) 374, which may be configured to receive addresses from the processor(s) 344 and translate those addresses to locations in memory (e.g., memory 364 and read only memory (ROM) 354) or to other circuits or devices.

The server 104 may be configured to provide a plurality of devices, such as computer system 106, access to various DAQ devices, e.g., via interface (e.g., network interface) 384.

In some embodiments, the server 104 may be accessed via a radio access network via interface 384, such as a 5G New Radio (5G NR) radio access network. In some embodiments, the server 104 may be accessed via a local area network (LAN), e.g., via an ethernet and/or Wi-Fi connection (e.g., supported by interface 384).

As described further subsequently herein, the server 104 may include hardware and software components for implementing or supporting implementation of features described herein. The processor 344 of the server 104 may be configured to implement or support implementation of part or all of the methods described herein, e.g., by executing program instructions stored on a memory medium (e.g., a non-transitory computer-readable memory medium). Alternatively, the processor 344 may be configured as a programmable hardware element, such as an FPGA (Field Programmable Gate Array), or as an ASIC (Application Specific Integrated Circuit), or a combination thereof. Alternatively (or in addition) the processor 344 of the server 104, in conjunction with one or more of the other components 354, 364, and/or 374 may be configured to implement or support implementation of part or all of the features described herein.

In addition, as described herein, processor(s) 344 may be comprised of one or more processing elements. In other words, one or more processing elements may be included in processor(s) 344. Thus, processor(s) 344 may include one or more integrated circuits (ICs) that are configured to perform the functions of processor(s) 344. In addition, each integrated circuit may include circuitry (e.g., first circuitry, second circuitry, etc.) configured to perform the functions of processor(s) 344.

### Simultaneously Sampled Daq Device

In existing implementations, there are generally two categories of data acquisition (DAQ) devices—multiplexed multifunction input/output (MIO) devices and simultaneously sampled multifunction input/output (SMIO) devices. MIO devices refer to a category of DAQ devices that can multiplex many input channels down to a single analog to digital converter (ADC). SMIO devices refer to a category of DAQ devices that have a per channel ADC that allows for higher speeds and simultaneous sampling of each channel. Thus, for cost reasons, SMIO devices tend to have a higher cost per channel than MIO devices while offering simultaneous sampling across a limited number of channels.

In addition, MIO DAQ devices tend to offer three different input configurations—differential mode (DIFF), referenced single-ended mode (RSE), and non-referenced single-ended mode (NRSE). In a DIFF configuration, an ADC measures a difference between two analog input (AI) signals (e.g., a positive AI signal (AI+) and a negative AI signal (AI−). In an RSE configuration, an ADC measures a difference between an AI signal and a common ground reference. In an NRSE configuration, an ADC measures a difference between an AI signal and a common remote ground reference (e.g., often referred to an AI sense). Note that, of these configurations, DIFF generally offers higher performance than RSE or NRSE, however, RSE and NRSE can offer simpler configurations and higher channel density since all channels can share a common reference thus reducing a number of reference pins required as compared to DIFF and allowing for higher channel density for a given package size.

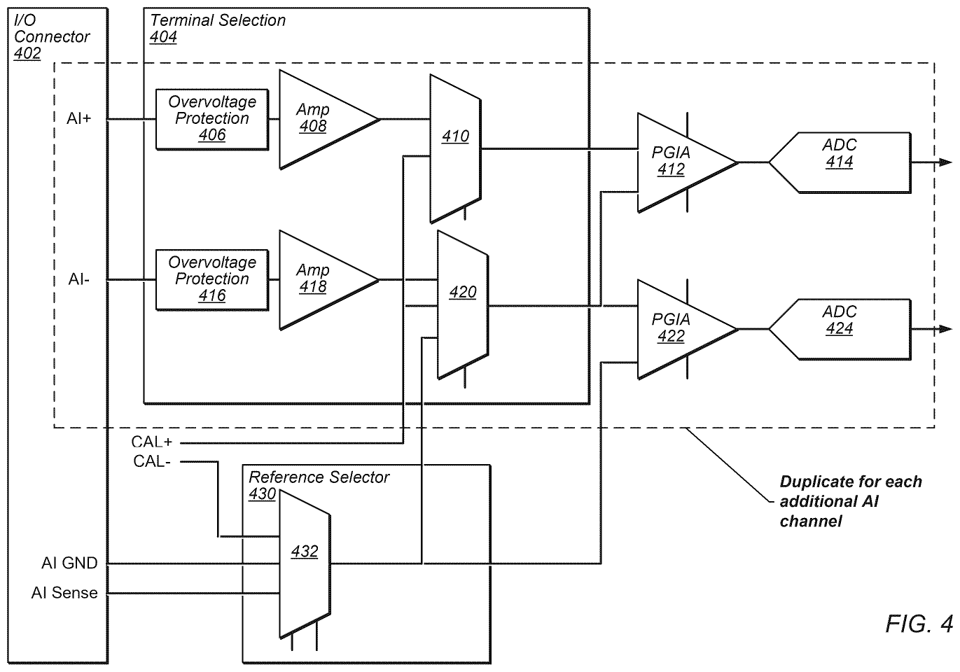

Further, SMIO DAQ devices tend to only support DIFF configurations. For example, FIG. 3 illustrates an example of a block diagram of an analog to digital converter (ADC) circuit of a SMIO DAQ device for a differential voltage measurement of an analog channel, according to current implementations. As shown, an SMIO DAQ device can include an input/output (I/O) connector 302 and a terminal 304. The I/O connection 302 can include connection points for a positive analog signal (AI+), a negative analog signal (AI−), and a common or ground. the AI+ signal can pass through an overvoltage protection circuit 306a and, similarly, the AI− signal can pass through an overvoltage protection circuit 306b. Both signals can be fed into instrumentation amplifier 308 (e.g., which can be an operation amplifier) which can amplify a voltage difference between the AI+ signal and the AI− signal to produce a voltage output that is fed into ADC 310. ADC 310 can then output a digital signal representative of the voltage output from instrumentation amplifier 308. Thus, the SMIO DAQ device can provide a differential voltage measurement for the analog channel. Note that an SMIO DAQ device can include multiple such circuits to support multiple analog channels, e.g., 4, 8, an/or 16 analog channels.

Thus, systems originally designed with MIO DAQ devices (e.g., using an RSE or NRSE configuration) cannot be readily upgraded to SMIO DAQ devices. Further, SMIO DAQ devices only support half the I/O density of MIO DAQ devices since there is no support for RSE or NRSE. Therefore, improvements are desirable.

Embodiments described herein provide systems, methods, and mechanisms for data acquisition (DAQ) devices, and more particularly to apparatuses, systems, and methods for a simultaneously sampled DAQ device with flexible input terminal configurations. For example, embodiments described herein provide additional switching mechanisms with an SMIO DAQ device to allow support of DIFF, RSE, and NRSE configurations. Such an SMIO DAQ device can then have identical capabilities, pinouts, and channel density as a similar MIO DAQ device (e.g., a 16 channel SMIO DAQ device can have identical capabilities, pinouts, and channel density as compared to a 16 channel MIO DAQ device) thereby easing system upgrades from MIO to SMIO while also providing higher channel density as compared to current SMIO DAQ devices. Further, to enhance such interchangeability between SMIO and MIO devices, driver software associated with the SMIO DAQ devices can be used to configure the SMIO DAQ device thereby limiting complexity for an end user. In addition, embodiments described herein allow for increased channel density for SMIO DAQ devices, e.g., an SMIO DAQ device as described herein can support 1 DIFF channel per ADC or 2 RSE/NRSE channels per ADC thereby doubling channel density.

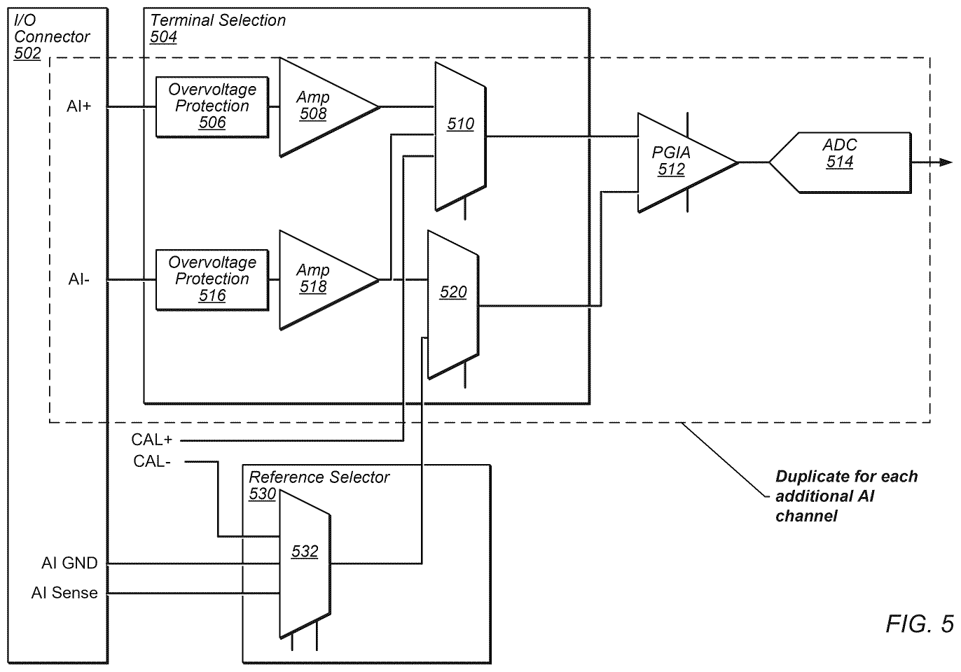

For example, FIGS. 4 and 5 illustrate examples of block diagrams of circuits for SMIO DAQ devices, according to some embodiments. Note that the circuits shown in FIGS. 4 and 5 show a single analog channel for simplicity but can be scaled, as noted in FIGS. 4 and 5, to accommodate additional analog channels as desired.

Turning to FIG. 4, such a circuit can include I/O connector 402. The I/O connector 402 can include AI+ and AI− inputs for one or more analog channels. In addition, I/O connector 402 can include inputs for an AI ground signal and an AI sense signal (e.g., common remote ground reference). The circuit can include reference selector circuit 430 and one or more terminal selection circuits 404. Note that each terminal selection circuit 404 can support an analog differential channel (e.g., allow inputs for an AI+ and AI− signal) and can be duplicated to support additional analog differential channels. Further, the circuit can include a calibration bus configured to generate a positive reference signal (CAL+) and a negative reference signal (CAL−). Further, the circuit can include, for each analog signal (e.g., AI+ and AI−), a programmable gain instrumentation amplifier (e.g., PGIAs 412 and 422) and an ADC (e.g., ADC 414 and 424).

Reference selector circuit 430 can include inputs for CAL−, AI ground (AI GND) and AI sense signals. These signals can be fed into signal selector 432. Signal selector 432 can be configured to provide any of the inputs as an output signal to terminal selection circuit 404 and PGIA 422. For example, depending on a measurement configuration, signal selector 432 can be configured (e.g., via programmable driver software) to output CAL−, AI GND, or AI sense.

Terminal selection circuit 404 can include overvoltage protection circuit 406 and amplifier 408 for an AI+ signal and overvoltage protection circuit 416 and amplifier 418 for an AI− signal. In addition, terminal selection circuit 404 can include signal selector circuits 410 and 420. More generally, terminal selection circuit 404 can include signal selector circuits for each AI signal supported by I/O connector 402. In other words, the terminal selection circuit 404 can include two signal selector circuits for each analog differential channel (e.g., a signal selector circuit for AI+ and a signal selector circuit for AI−). As shown, signal selector circuit 410 can support AI+ and support inputs for AI+ signals outputted from amplifier 408 as well as from CAL+. Signal selector 410 can be configured to provide any of the inputs as an output signal to PGIA 412. For example, depending on a measurement configuration, signal selector 410 can be configured (e.g., via programmable driver software) to output AI+ or CAL+. Additionally, signal selector circuit 420 can support AI− and support inputs for AI− signals outputted from amplifier 418, CAL+, and reference selector 430 (e.g., a signal output from signal selector 432 such as CAL−, AI GND, or AI sense). Signal selector 420 can be configured to provide any of the inputs as an output signal to PGIA 412 and PGIA 422. For example, depending on a measurement configuration, signal selector 420 can be configured (e.g., via programmable driver software) to output AI−, CAL+, CAL−, AI GND, or AI sense.

PGIA 412 can amplify a voltage difference between a signal outputted from signal selector 410 and signal selector 420 to produce a voltage output that is fed into ADC 414. ADC 414 can then output a digital signal representative of the voltage output from PGIA 412. Thus, depending on the configuration of signal selectors 410, 420, and 432, ADC 414 can output a digital signal representative of a differential measurement of an AI channel (e.g., a voltage difference between AI+ and AI−), a single ended measurement of AI+ , either referenced (e.g., with respect to AI ground) or non-referenced (e.g., with respect to AI sense), or a calibration measurement (e.g., a voltage difference between CAL+and CAL−). Further, depending on the configuration of signal selectors 420 and 430, PGIA 422 can output a digital signal representation of a signal ended measurement of AI−, either referenced (e.g., with respect to AI ground) or non-referenced (e.g., with respect to AI sense).

Hence, according to the embodiment described with respect to FIG. 4, an SMIO DAQ device can be configured, e.g., via programmable driver software, to simultaneously sample AI channels in differential mode or simultaneously sample AI+ and AI− signals in single ended mode (RSE or NRSE).

Turning to FIG. 5, such a circuit can include I/O connector 502. The I/O connector 502 can include AI+ and AI− inputs for one or more analog channels. In addition, I/O connector 502 can include inputs for an AI ground signal and an AI sense signal (e.g., common remote ground reference). The circuit can include reference selector circuit 530 and one or more terminal selection circuits 504. Note that each terminal selection circuit 504 can support an analog differential channel (e.g., allow inputs for an AI+ and AI− signal) and can be duplicated to support additional analog differential channels. Further, the circuit can include a calibration bus configured to generate a positive reference signal (CAL+) and a negative reference signal (CAL−). Further, the circuit can include, for each analog channel, a programmable gain instrumentation amplifier (e.g., PGIA 512) and an ADC (e.g., ADC 514).

Reference selector circuit 530 can include inputs for CAL−, AI ground (AI GND) and AI sense signals. These signals can be fed into signal selector 532. Signal selector 532 can be configured to provide any of the inputs as an output signal to terminal selection circuit 504. For example, depending on a measurement configuration, signal selector 532 can be configured (e.g., via programmable driver software) to output CAL−, AI GND, or AI sense.

Terminal selection circuit 504 can include overvoltage protection circuit 506 and amplifier 508 for an AI+ signal and overvoltage protection circuit 516 and amplifier 518 for an AI− signal. In addition, terminal selection circuit 504 can include signal selector circuits 510 and 520. More generally, terminal selection circuit 504 can include signal selector circuits for each AI signal supported by I/O connector 502. In other words, the terminal selection circuit 504 can include two signal selector circuits for each analog differential channel (e.g., a signal selector circuit for AI+ and a signal selector circuit for AI−). As shown, signal selector circuit 510 can support AI+ and support inputs for AI+ signals outputted from amplifier 508, AI− signals outputted from amplifier 518, and CAL+. Signal selector 510 can be configured to provide any of the inputs as an output signal to PGIA 512. For example, depending on a measurement configuration, signal selector 510 can be configured (e.g., via programmable driver software) to output AI+, AI−, or CAL+. Additionally, signal selector circuit 520 can support AI− and support inputs for AI− signals outputted from amplifier 518, CAL+ and reference selector 530 (e.g., a signal output from signal selector 532 such as CAL−, AI GND, or AI sense). Signal selector 520 can be configured to provide any of the inputs as an output signal to PGIA 512. For example, depending on a measurement configuration, signal selector 520 can be configured (e.g., via programmable driver software) to output AI−, CAL−, AI GND, or AI sense.

PGIA 512 can amplify a voltage difference between a signal outputted from signal selector 510 and signal selector 520 to produce a voltage output that is fed into ADC 514. ADC 514 can then output a digital signal representative of the voltage output from PGIA 512. Thus, depending on the configuration of signal selectors 510, 520, and 532, ADC 514 can output a digital signal representative of a differential measurement of an AI channel (e.g., a voltage difference between AI+ and AI−), a single ended measurement of AI+ , either referenced (e.g., with respect to AI ground) or non-referenced (e.g., with respect to AI sense), a single ended measurement of AI−, either referenced (e.g., with respect to AI ground) or non-referenced (e.g., with respect to AI sense), or a calibration measurement (e.g., a voltage difference between CAL+ and CAL−).

Hence, according to the embodiment described with respect to FIG. 5, an SMIO DAQ device can be configured, e.g., via programmable driver software, to simultaneously sample AI channels in differential mode or pseudo-simultaneously sample AI+ and AI− signals in single ended mode (RSE or NRSE), e.g., all AI+ channels sampled simultaneously and then all AI− channels sample simultaneously.

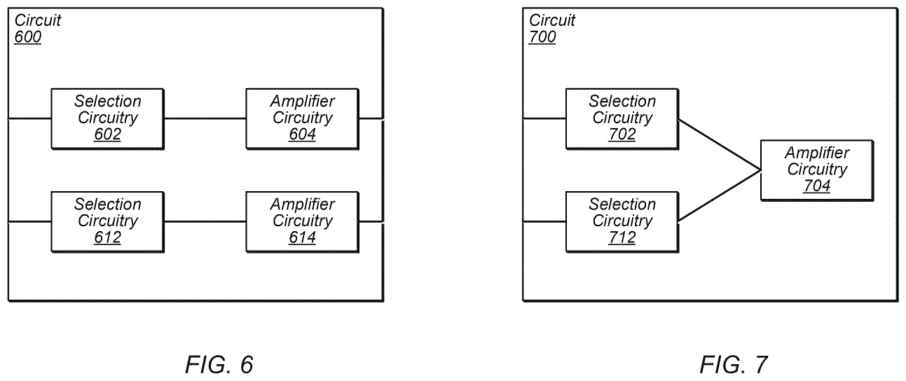

FIGS. 6 and 7 illustrate examples of simplified block diagrams of circuits for SMIO DAQ devices, according to some embodiments. Note that the circuits shown in FIGS. 6 and 7 support a single analog channel for simplicity, however such circuits can be scaled to accommodate additional analog channels as desired.

Turning to FIG. 6, as shown, circuit 600 can include first selection circuitry (e.g., selection circuitry 602) that is in communication with a first instrumentation amplifier (e.g. amplifier circuitry 604) and second selection circuitry (e.g., selection circuitry 612) that is in communication with a second instrumentation amplifier (e.g. amplifier circuitry 614). The first selection circuitry can be configured (e.g., via a programmable driver software) to output one of a positive analog input signal or a positive calibration signal. The second selection circuitry can be configured (e.g., via the programmable driver software) to output one of a negative analog input signal, the positive calibration signal, or a ground reference signal. The first instrumentation amplifier can be configured (e.g., via the programmable driver software) to output a first analog signal corresponding to a voltage difference between a first signal output from the first selection circuitry and a second signal output from the second selection circuitry. The second instrumentation amplifier can be configured (e.g., via the programmable driver software) to output a second analog signal corresponding to a voltage difference between the second signal output from the second selection circuitry and the ground reference signal.

In some instances, circuit 600 can further include a first analog to digital converter that can be configured (e.g., via the programmable driver software) to digitize the first analog signal. In addition, circuit 600 can further include a second analog to digital converter that can be configured (e.g., via the programmable driver software) to digitize the second analog signal.

In some instances, circuit 600 can further include third selection circuitry that can be configured (e.g., via the programmable driver software) to output one of an analog common ground reference signal, an analog common remote ground reference signal, or a negative calibration signal.

In some instances, circuit 600 can further include a calibration bus that can be configured (e.g., via the programmable driver software) to output the positive calibration signal. In addition, the calibration bus can be further configured (e.g., via the programmable driver software) to output a negative calibration signal.

In some instances, the first instrumentation amplifier can include and/or be a programmable gain instrumentation amplifier that can be configured the via programmable driver software. Similarly, the second instrumentation amplifier can include and/or be a programmable gain instrumentation amplifier that can be configured via the programmable driver software.

In some instances, circuit 600 can further include an input/output connector. The input/output connector can include inputs (e.g., connector ports and/or connector pins) for one or more analog (input) channels, an analog ground signal, and an analog sense signal. In addition, the input/output connector can also include one or more outputs (e.g., connector ports and/or connector pins) for one or more analog (output) channels. Note that each analog channel of the one or more analog channels (including analog input channels and/or analog output channels) can include a first input for a positive analog signal and a second input for a negative analog signal.

Turning to FIG. 7, as shown, circuit 700 can include first selection circuitry (e.g., selection circuitry 702) and second selection circuitry (e.g., selection circuitry 712) that are that is in communication with an instrumentation amplifier (e.g. amplifier circuitry 704). The first selection circuitry can be configured (e.g., via a programmable driver software) to output one of a positive analog input signal, a negative analog input signal, or a positive calibration signal. The second selection circuitry can be configured (e.g., via the programmable driver software) to output one of the negative analog input signal or a ground reference signal. The instrumentation amplifier can be configured (e.g., via the programmable driver software) to output a first analog signal corresponding to a voltage difference between a first signal output from the first selection circuitry and a second signal output from the second selection circuitry.

In some instances, circuit 700 can further include an analog to digital converter that can be configured (e.g., via the programmable driver software) to digitize the first analog signal.

In some instances, circuit 700 can further include third selection circuitry that can be configured (e.g., via the programmable driver software) to output one of an analog common ground reference signal, an analog common remote ground reference signal, or a negative calibration signal.

In some instances, circuit 700 can further include a calibration bus that can be configured (e.g., via the programmable driver software) to output the positive calibration signal. In addition, the calibration bus can be further configured (e.g., via the programmable driver software) to output a negative calibration signal.

In some instances, the first instrumentation amplifier can include and/or be a programmable gain instrumentation amplifier that can be configured the via programmable driver software. Similarly, the second instrumentation amplifier can include and/or be a programmable gain instrumentation amplifier that can be configured via the programmable driver software.

In some instances, circuit 700 can further include an input/output connector. The input/output connector can include inputs (e.g., connector ports and/or connector pins) for one or more analog (input) channels, an analog ground signal, and an analog sense signal. In addition, the input/output connector can also include one or more outputs (e.g., connector ports and/or connector pins) for one or more analog (output) channels. Note that each analog channel of the one or more analog channels (including analog input channels and/or analog output channels) can include a first input for a positive analog signal and a second input for a negative analog signal.

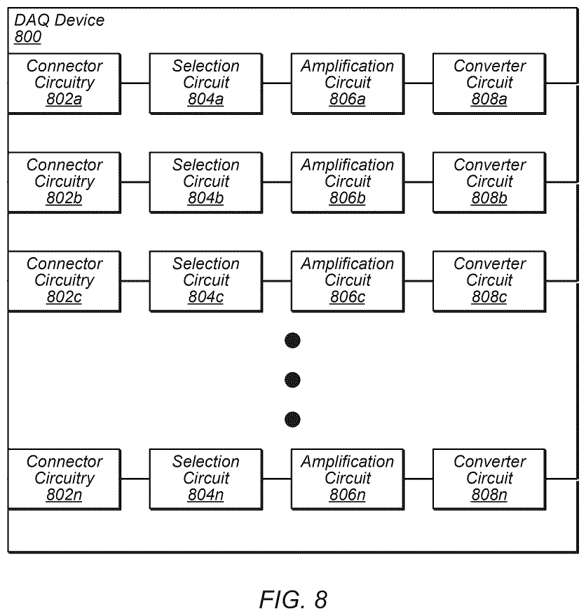

FIG. 8 illustrates an example of a simplified block diagram of a DAQ device, according to some embodiments. In some instances, DAQ device 800 can be configured, e.g., via programmable driver software, to simultaneously sample AI channels in differential mode or simultaneously sample AI+ and AI− signals in single ended mode (RSE or NRSE). In some instances, DAQ device 800 can be configured, e.g., via programmable driver software, to simultaneously sample AI channels in differential mode or pseudo-simultaneously sample AI+ and AI− signals in single ended mode (RSE or NRSE), e.g., all AI+ channels sampled simultaneously and then all AI− channels sample simultaneously.

As shown, DAQ device 800 can include a plurality of signal selection circuits (e.g., selection circuits 806a-n) and a plurality of amplification circuits (e.g., amplification circuits 806a-n). Further, DAQ device 800 can include a plurality of connector circuitry (e.g., connector circuitry 802a-n) and a plurality of converter circuits (e.g., converter circuits 808a-n). Note that, as shown, each signal selection circuit can have a corresponding amplification circuit, converter circuit, and connector circuitry.

In some instances, each signal selection circuit can be configured to output, to a corresponding amplification circuit (e.g., such as selection circuit 804a outputting to amplification circuit 806a), a first analog signal and a second analog signal. The first analog signal can include and/or be one of a positive analog input signal or a positive calibration signal. The second analog signal can include and/or be one of a negative analog input signal, the positive calibration signal, or a ground reference signal. Further, each amplification circuit can be configured to at least output a third analog signal corresponding to a voltage difference between the first analog signal and the second analog signal. In some configurations, each amplification circuit can also be configured to output a fourth analog signal corresponding to a voltage difference between the second signal and the ground reference signal. Additionally, in such instances, each converter circuit can include a first analog to digital converter configured to digitize the third analog signal and a second analog to digital converter configured to digitize the fourth analog signal. Hence, DAQ device 800 can be configured, e.g., via programmable driver software, to simultaneously sample AI channels in differential mode or simultaneously sample AI+ and AI− signals in single ended mode (RSE or NRSE).

In some instances, each signal selection circuit can be configured to output, to the corresponding amplification circuit, a first analog signal and a second analog signal. The first analog signal can include and/or be a positive analog input signal, a negative analog input signal, or a positive calibration signal. The second analog signal can include and/or be one of the negative analog input signal or a ground reference signal. Further, each amplification circuit can be configured to output a third analog signal corresponding to a voltage difference between the first analog signal and the second analog signal. Additionally, in such instances, each converter circuit can include an analog to digital converter configured to digitize the third analog signal. Hence, DAQ device 800 can be configured, e.g., via programmable driver software, to simultaneously sample AI channels in differential mode or pseudo-simultaneously sample AI+ and AI− signals in single ended mode (RSE or NRSE), e.g., all AI+ channels sampled simultaneously and then all AI− channels sample simultaneously.

The DAQ device 800 can further include a ground reference selection circuit. The ground reference selection circuit can be configured to output one of an analog common ground reference signal, an analog common remote ground reference signal, or the negative calibration signal. In some instances, the ground reference selection circuit can be connected to (e.g., receive inputs from) inputs for the analog ground signal and the analog sense signal.

The DAQ device 800 can further include a calibration bus. The calibration bus can be configured to output the positive calibration signal and/or a negative calibration signal.

In some instances, each connector circuitry (e.g., such connector circuitry 802a) can include inputs for an analog channel. The inputs for the analog channel can include a first input for a positive analog signal and a second input for a negative analog signal.

In some instances, DAQ device 800 can further include output connection circuitry to output one or more analog channels, where each analog channel includes a positive analog signal and a negative analog signal.

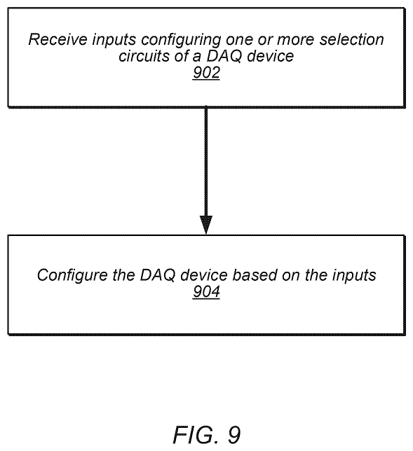

FIG. 9 illustrates a block diagram of an example of a method for configuring a DAQ device, according to some embodiments. The method shown in FIG. 9 may be used in conjunction with any of the systems, methods, or devices shown in the Figures, among other devices. In various embodiments, some of the method elements shown may be performed concurrently, in a different order than shown, or may be omitted. Additional method elements may also be performed as desired. As shown, this method may operate as follows.

At 902, inputs can be received to configure one or more selection circuits of a DAQ device, such as DAQ device 800. The inputs can be received via a computer system, such as computer system 106 and/or via a server, such as server 104. In some instances, the inputs can be received via a network connection to the computer system or server (e.g., wired and/or wireless). In some instances, the inputs can be received via a bus (e.g., such as PCI, PCIe, and/or USB). The DAQ device can include a plurality of signal selection circuits and a plurality of amplification circuits. Further, the DAQ device can include a plurality of connector circuitry and a plurality of converter circuits. Note that each signal selection circuit can have a corresponding amplification circuit, converter circuit, and connector circuitry.

At 904, the DAQ device can be configured based on the inputs.

For example, in some instances, the inputs can configure each signal selection circuit to output, to a corresponding amplification circuit a first analog signal and a second analog signal. The inputs can indicate that the first analog signal is one of a positive analog input signal or a positive calibration signal and that the second analog signal is one of a negative analog input signal, the positive calibration signal, or a ground reference signal. Further, the inputs can configure each amplification circuit to at least output a third analog signal corresponding to a voltage difference between the first analog signal and the second analog signal. In addition, the inputs can configuration each amplification circuit to output a fourth analog signal corresponding to a voltage difference between the second signal and the ground reference signal. Additionally, in such instances, each converter circuit can include a first analog to digital converter that the inputs can configure to digitize the third analog signal and a second analog to digital converter the inputs can configure to digitize the fourth analog signal. Hence, the DAQ device can be configured, e.g., via inputs, to simultaneously sample AI channels in differential mode or simultaneously sample AI+ and AI− signals in single ended mode (RSE or NRSE).

As another example, in some instances, the inputs can configure each signal selection circuit to output, to the corresponding amplification circuit, a first analog signal and a second analog signal. The inputs can indicate that the first analog signal is a positive analog input signal, a negative analog input signal, or a positive calibration signal and that the second analog signal is one of the negative analog input signal or a ground reference signal. Further, the inputs can configure each amplification circuit to output a third analog signal corresponding to a voltage difference between the first analog signal and the second analog signal. Additionally, in such instances, each converter circuit can include an analog to digital converter the inputs can configure to digitize the third analog signal. Hence, the DAQ device can be configured, e.g., via the inputs, to simultaneously sample AI channels in differential mode or pseudo-simultaneously sample AI+ and AI− signals in single ended mode (RSE or NRSE), e.g., all AI+ channels sampled simultaneously and then all AI− channels sample simultaneously.

In some instances, the DAQ device can further include a ground reference selection circuit. Thus, the inputs can configure ground reference selection circuit to output one of an analog common ground reference signal, an analog common remote ground reference signal, or the negative calibration signal. In some instances, the ground reference selection circuit can be connected to (e.g., receive inputs from) inputs for the analog ground signal and the analog sense signal.

In some instances, the DAQ device can further include a calibration bus. Thus, the inputs can configure the calibration bus to output the positive calibration signal and/or a negative calibration signal.

Embodiments of the present disclosure may be realized in any of various forms. For example, some embodiments may be realized as a computer-implemented method, a computer-readable memory medium, or a computer system. Other embodiments may be realized using one or more custom-designed hardware devices such as ASICs. Still other embodiments may be realized using one or more programmable hardware elements such as FPGAs.

In some embodiments, a non-transitory computer-readable memory medium may be configured so that it stores program instructions and/or data, where the program instructions, if executed by a computer system, cause the computer system to perform a method, e.g., any of the method embodiments described herein, or, any combination of the method embodiments described herein, or, any subset of any of the method embodiments described herein, or, any combination of such subsets.

In some embodiments, a device (e.g., a computer system 106) may be configured to include a processor (or a set of processors) and a memory medium, where the memory medium stores program instructions, where the processor is configured to read and execute the program instructions from the memory medium, where the program instructions are executable to implement any of the various method embodiments described herein (or, any combination of the method embodiments described herein, or, any subset of any of the method embodiments described herein, or, any combination of such subsets). The device may be realized in any of various forms.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A circuit, comprising:
first selection circuitry configured to output one of a positive analog input signal or a positive calibration signal;
second selection circuitry configured to output one of a negative analog input signal, the positive calibration signal, or a ground reference signal;
a first instrumentation amplifier configured to output a first analog signal corresponding to a voltage difference between a first signal output from the first selection circuitry and a second signal output from the second selection circuitry; and
a second instrumentation amplifier configured to output a second analog signal corresponding to a voltage difference between the second signal output from the second selection circuitry and the ground reference signal.

2. The circuit of claim 1, further comprising:
a first analog to digital converter configured to digitize the first analog signal; and
a second analog to digital converter configured to digitize the second analog signal.

3. The circuit of claim 1, further comprising:
third selection circuitry configured to output one of an analog common ground reference signal, an analog common remote ground reference signal, or a negative calibration signal.

4. The circuit of claim 1, further comprising:
a calibration bus configured to output the positive calibration signal.

5. The circuit of claim 1,
wherein the first selection circuitry and the second selection circuitry are configurable via programmable driver software.

6. The circuit of claim 1, further comprising:
an input/output connector comprising inputs for one or more analog channels, an analog ground signal, and an analog sense signal.

7. The circuit of claim 6,
wherein inputs for the one or more analog channels comprises, for each analog channel of the one or more analog channels, a first input for a positive analog signal and a second input for a negative analog signal.

8. A circuit, comprising:
first selection circuitry configured to output one of a positive analog input signal, a negative analog input signal, or a positive calibration signal;
second selection circuitry configured to output one of the negative analog input signal or a ground reference signal; and
an instrumentation amplifier configured to output an analog signal corresponding to a voltage difference between a first signal output from the first selection circuitry and a second signal output from the second selection circuitry.

9. The circuit of claim 8, further comprising:
an analog to digital converter configured to digitize the analog signal.

10. The circuit of claim 8, further comprising:
third selection circuitry configured to output one of an analog common ground reference signal, an analog common remote ground reference signal, or a negative calibration signal.

11. The circuit of claim 8, further comprising:
a calibration bus configured to output the positive calibration signal.

12. The circuit of claim 8,
wherein the first selection circuitry and the second selection circuitry are configurable via programmable driver software.

13. The circuit of claim 8,
wherein the instrumentation amplifier comprises a programmable gain instrumentation amplifier configurable via programmable driver software.

14. The circuit of claim 8, further comprising:
an input/output connector comprising inputs for one or more analog channels, an analog ground signal, and an analog sense signal.

15. A data acquisition device, comprising:
a plurality of signal selection circuits; and
a plurality of amplification circuits;
wherein each signal selection circuit has a corresponding amplification circuit;
wherein each signal selection circuit of the plurality of signal selection circuits is configured to output, to the corresponding amplification circuit, a first analog signal comprising one of a positive analog input signal or a positive calibration signal and a second analog signal comprising one of a negative analog input signal, the positive calibration signal, or a ground reference signal; and
wherein each amplification circuit of the plurality of amplification circuits is configured to output a third analog signal corresponding to a voltage difference between the first analog signal and the second analog signal and a fourth analog signal corresponding to a voltage difference between the second analog signal and the ground reference signal.

16. The data acquisition device of claim 15, further comprising:
a plurality of converter circuits, wherein each signal selection circuit has a corresponding converter circuit.

17. The data acquisition device of claim 16,
wherein each converter circuit of the plurality of converter circuits comprises:
a first analog to digital converter configured to digitize the third analog signal; and
a second analog to digital converter configured to digitize the fourth analog signal.

18. The data acquisition device of claim 15, further comprising:
a ground reference selection circuit configured to output one of an analog common ground reference signal, an analog common remote ground reference signal, or a negative calibration signal.

19. The data acquisition device of claim 15, further comprising:
connector circuitry comprising inputs for one or more analog channels, an analog ground signal, and an analog sense signal, wherein each signal selection circuit has a corresponding analog channel.

20. The data acquisition device of claim 19,
wherein inputs for the one or more analog channels comprises, for each analog channel of the one or more analog channels, a first input for a positive analog signal and a second input for a negative analog signal.
